(19) United States
(12) Patent Application Publication
(10) Pub. No.: US 2014/0285966 A1
(43) Pub. Date: Sep. 25, 2014

(54) SERVER CABINET

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: XIAN-XIU TANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/973,986

(22) Filed: Aug. 22, 2013

(30) Foreign Application Priority Data
Mar. 20, 2013 (CN) 2013100888418

(51) Int. Cl. H05K 7/20

(52) U.S. Cl. CPC H05K 7/20709; H05K 7/20409
USPC 361/679.54

(57) ABSTRACT

A server cabinet includes a cabinet body and a heat dissipation apparatus attached to one side of the cabinet body. The heat dissipation apparatus includes a thermal conductive film, a heat sink, and a side cover fixed to the cabinet body. The side cover defines an opening for receiving the heat sink. The thermal conductive film is adhered to the side of the cabinet body. The heat sink contacts with the thermal conductive film.

### BACKGROUND

1. Technical Field

The present disclosure relates to a server cabinet.

2. Description of Related Art

A server cabinet usually includes a number of server modules. The server modules are always compactly arranged in the cabinet, which weakens the heat dissipation effect.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an embodiment of a server cabinet.

FIG. 2 is an exploded, isometric view of the server cabinet of FIG. 1, wherein the server cabinet includes a heat dissipation apparatus.

FIG. 3 is an exploded, isometric view of the heat dissipation apparatus of FIG. 2, but viewed from another perspective.

FIG. 4 is an enlarged view of the circled portion IV of FIG. 3.

### DETAILED DESCRIPTION

The disclosure, including the accompanying drawing, is illustrated by way of examples and not by way of limitation. It should be noted that references to “an” or “one” embodiment in this disclosure are not necessarily to the same embodiment, and such references mean at least one.

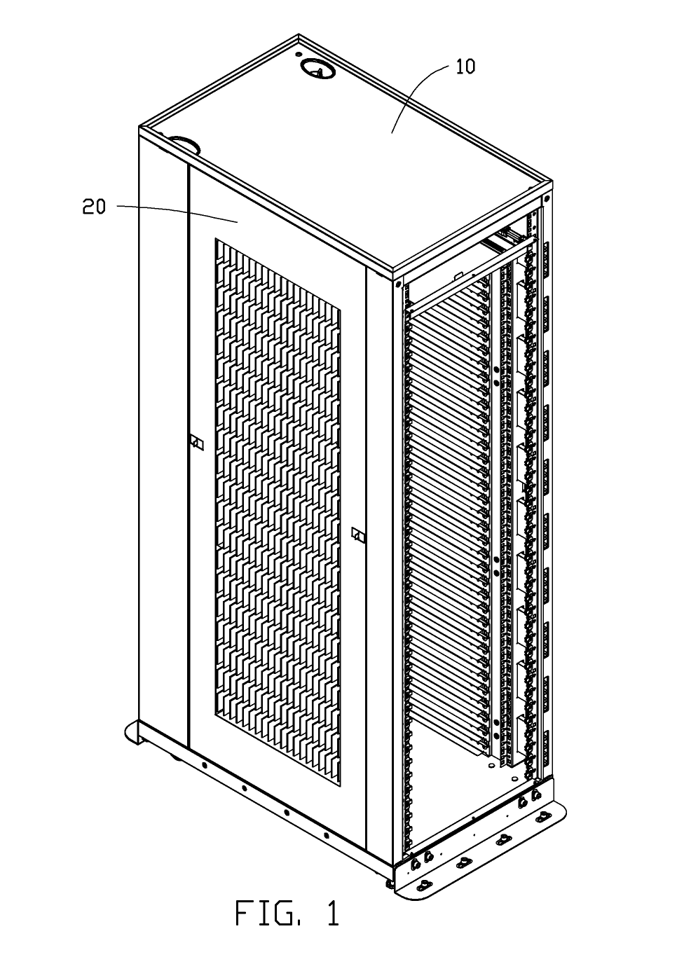

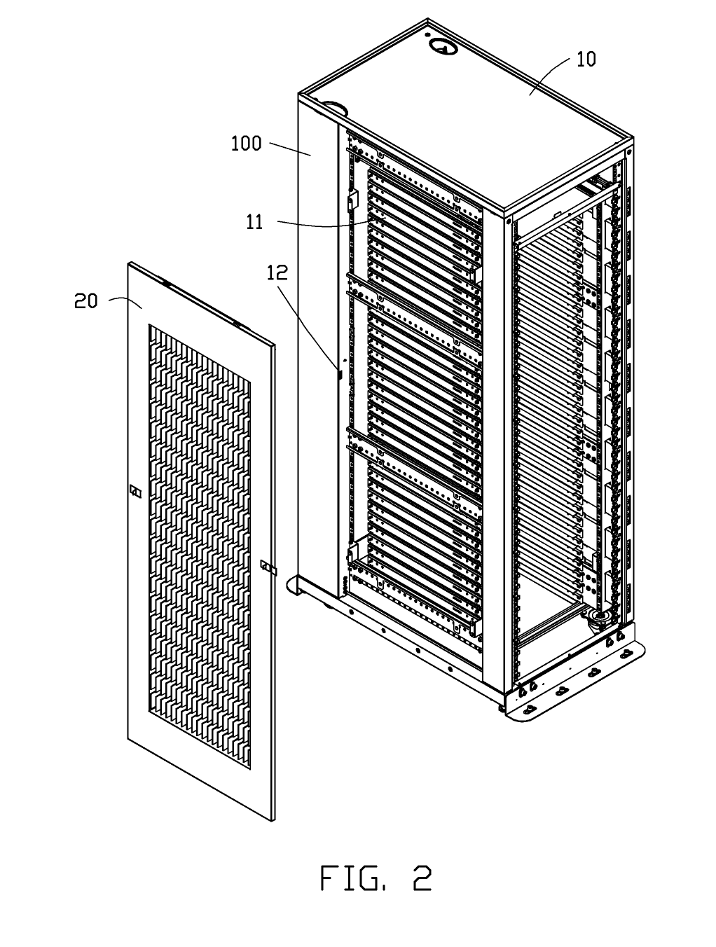

FIG. 1 and FIG. 2 show an exemplary embodiment of a server cabinet. The server cabinet includes a cabinet body 10 and a heat dissipation apparatus 20.

The cabinet body 10 includes four upright supporting poles 100 and a plurality of racks 11 fixed to two of the supporting poles 100 at a same side of the cabinet body 10. Two opposite mounting holes 12 are defined in the two supporting poles 100.

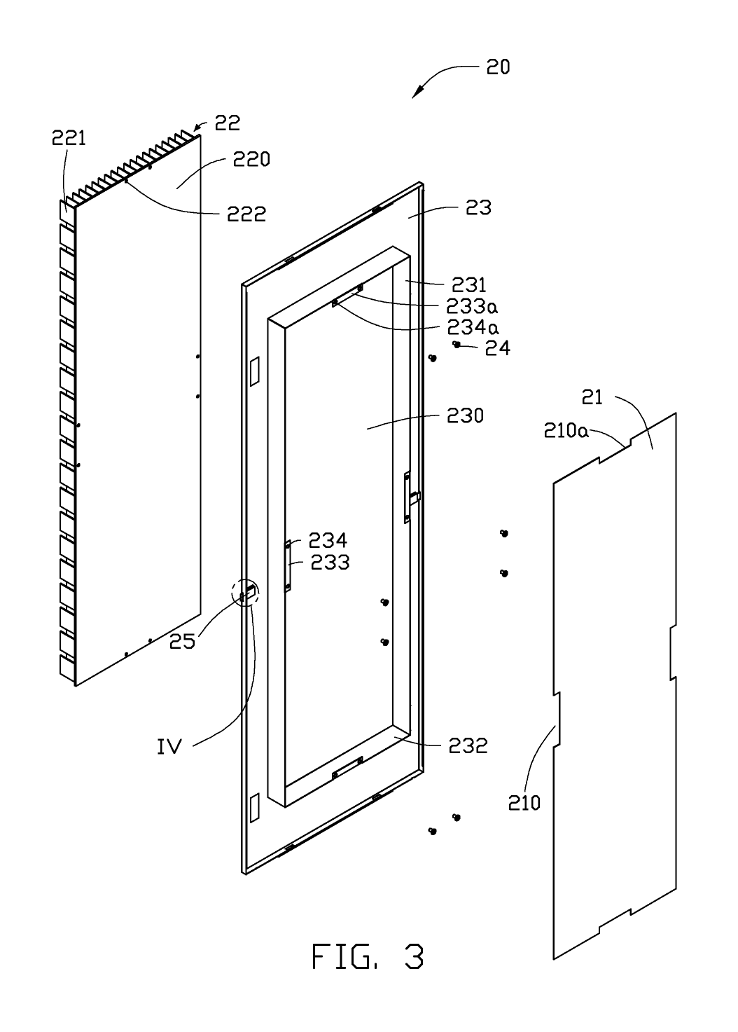

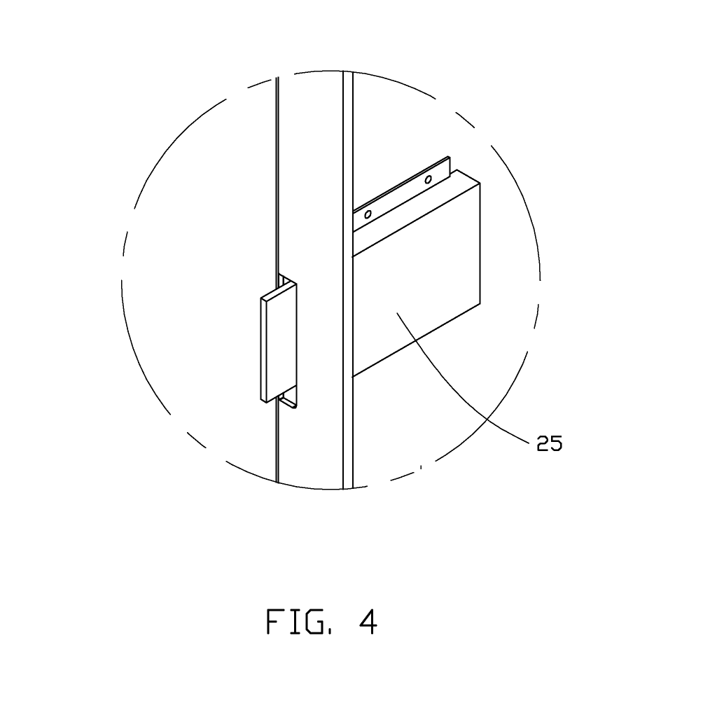

FIG. 3 and FIG. 4 show that the heat dissipation apparatus 20 includes a thermal conductive film 21, a heat sink 22, a side cover 23, a plurality of screws 24, and two latches 25.

The heat sink 22 includes a substantially rectangular base 220 and a plurality of fins 221 extending from a first side of the base 220. A plurality of screws holes 222 is defined in four sides of the base 220.

The side cover 23 defines a substantially rectangular opening 230 in a center. Two opposite first plates 231 and two opposite second plates 232 extending in from the side cover 23 and bounding the opening 230. A mounting piece 233 extends toward the opening 230 from a middle of each first plate 231. A mounting piece 233a extends toward the opening 230 from a middle of each second plate 232. Each mounting piece 233 defines a through hole 234. Each mounting piece 233a defines a through hole 234a. The latches 25 are movably attached to opposite sides of the side cover 23, in a direction perpendicular to the first plates 231.

The thermal conductive film 21 is substantially rectangular, and defines two opposite cutouts 210 and two opposite cutouts 210a in four sides. The thermal conductive film 21 is viscous and flexible.

In assembly, the screws 24 are utilized to extend through the through holes 234 and 234a to screw in the screw holes 222, to fix the heat sink 22 in the opening 230. The thermal conductive film 21 is adhered to the racks 11. The side cover 23 is then attached to the cabinet body 10, with the base 220 contacting with the thermal conductive film 21. The latches 25 are operated to latch in the mounting holes 12, to fix the side cover 23 to the cabinet body 10. The cutouts 210 and 210a of the thermal conductive film 21 are used for avoiding the mounting pieces 233 and 233a, respectively.

When the server modules operate, the heat generated by the server modules is transferred to the racks 11, and then is transferred to the heat sink 22 through the thermal conductive film 21, for efficient heat dissipation.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A server cabinet comprising:
a cabinet body comprising a plurality of racks; and
a heat dissipation apparatus comprising a thermal conductive film, a heat sink, and a side cover fixed to the cabinet body, wherein the side cover defines an opening for receiving the heat sink, the thermal conductive film is adhered to the racks, the heat sink contacts with the thermal conductive film.

2. The server cabinet of claim 1, wherein the heat sink comprises a base and a plurality of fins extending out from the base, the base contacts with the thermal conductive film.

3. The server cabinet of claim 2, wherein the side cover comprises two opposite first plates and two opposite second plates extending from the side cover and bounding the opening, the first and second plates each form a mounting piece for fixing the base of the heat sink.

4. The server cabinet of claim 1, wherein two latches are mounted to opposite sides of the side cover, for latching the side cover to the cabinet body.
